(19) United States
(12) Patent Application Publication
(10) Pub. No.: US 2025/0201691 A1
(43) Pub. Date: Jun. 19, 2025

(54) POWER MODULE

(71) Applicants: Hyundai Motor Company, Seoul (KR); Kia Corporation, Seoul (KR)

(72) Inventors: Nam Sik KONG, Hwaseong-Si (KR); Sung Taek HWANG, Seoul (KR); Jun Hee PARK, Hwaseong-Si (KR); Se Yoon JEONG, Hwaseong-Si (KR)

(73) Assignees: Hyundai Motor Company, Seoul (KR); Kia Corporation, Seoul (KR)

(21) Appl. No.: 18/799,407

(22) Filed: Aug. 9, 2024

(30) Foreign Application Priority Data
Dec. 14, 2023 (KR) 10-2023-0181911

(51) Int. Cl. H01L 23/498; H01L 23/00; H01L 23/31; H01L 23/46

(52) U.S. Cl. CPC H01L 23/49833; H01L 23/46; H01L 23/49811; H01L 23/3107; H01L 24/32; H01L 24/33; H01L 2224/2612; H01L 2224/32225; H01L 2224/33181

(57) ABSTRACT

A power module includes first and second substrates spaced from each other, at least one semiconductor chip, and at least one third substrate, in which the at least one third substrate includes at least one conductive pattern including one end portion electrically connected to any one of the semiconductor chips, and the other end portion extending outwardly from the first and second substrates.

### CROSS-REFERENCE TO RELATED APPLICATION

The present application claims priority to Korean Patent Application No. 10-2023-0181911, filed on Dec. 14, 2023, the entire contents of which is incorporated herein for all purposes by this reference.

### BACKGROUND OF THE PRESENT DISCLOSURE

### Field of the Present Disclosure

The present disclosure relates to a power module including an internal structure improved to improve electric power performance and cooling performance.

### Description of Related Art

Recently, as there is increasing interest in environment, the number of environmental-friendly vehicles using electric motors as power sources increases. The environmental-friendly vehicle is called a motorized vehicle. The representative examples of the environmental-friendly vehicles include an electric vehicle (EV) and a hybrid electric vehicle (HEV).

The motorized vehicle is provided with an inverter configured to convert direct current power into alternating current power when the motor operates. The inverter generally includes one or a plurality of power modules having a semiconductor chip configured to perform a switching function.

In general, a pattern is formed on a surface of a substrate in the power module, and the power module is connected to a signal lead by wire bonding or the like, so that the power module may perform signal connection with the outside thereof. Furthermore, a spacer or the like may be inserted into the power module to define a high-current path, and the power module may be connected to a power lead to expand the high-current path to the outside thereof.

A structural constraint may occur when an appropriate pattern, wire bonding, a spacer, and the like are provided in the power module. Therefore, there is a demand for a solution to variously change an internal structure of the power module to cope with the structural constraint caused by the pattern, the wire bonding, the spacer, and the like and improve electric power performance, cooling performance, and the like.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing power module configured for improving electric power performance and cooling performance by improving an internal connection structure.

Technical problems of the present disclosure are not limited to the aforementioned technical problems, and other technical problems, which are not mentioned above, may be clearly understood by those skilled in the art from the following descriptions.

To achieve the above-mentioned object, an exemplary embodiment of the present disclosure provides a power module including: first and second substrates spaced from each other; at least one semiconductor chip disposed in a separation space located between the first and second substrates; and at least one third substrate disposed in the separation space located between the first and second substrates, in which the at least one third substrate includes at least one conductive pattern including a first end portion electrically connected to a signal pad of the at least one semiconductor chip, and a second end portion extending outwardly from the first and second substrates, the third substrate having a smaller thickness of each of the first and second substrates.

For example, the at least one third substrate may include: a film portion extending along the at least one conductive pattern and made of a flexible material to insulate the at least one conductive pattern; and a plurality of terminal portions formed at first and second opposite end portions of the conductive pattern and connected to the outside and the signal pad of the at least one semiconductor chip.

For example, the power module may further include: a first lead including one end portion connected to the other end portion of the third substrate, and the other end portion connected to the outside thereof, the first lead being configured to electrically connect the semiconductor chip and the outside thereof.

For example, the power module may further include: a second lead connected to the first and second substrates and electrically connecting the first and second substrates and the outside thereof.

For example, the second lead may extend outwardly from an inside of the separation space formed between the first substrate and the second substrate, one surface of the second lead may be joined to the first substrate in the separation space, and the other surface of the second lead may be joined to the second substrate.

For example, the first substrate and the second substrate may have different thicknesses.

For example, the at least one semiconductor chip may be joined to one surface of the first substrate directed toward the separation space, and the first substrate may have a larger thickness than the second substrate.

For example, the power module may further include: a first cooling channel disposed on a second surface of the first substrate, and a cooling fluid flows in the first cooling channel.

For example, a cooling fin may be formed on the other surface of the first substrate and provided to be in contact with the cooling fluid.

For example, the power module may further include: a second cooling channel disposed on one surface of the second substrate directed toward the outside thereof, and a cooling fluid flows in the second cooling channel.

For example, the second cooling channel may be thermally connected to the second substrate through a heat transfer material disposed between one surface of the second substrate and the second cooling channel.

For example, the second cooling channel may be joined to one surface of the second substrate.

For example, the power module may further include: at least one chip spacer disposed in the separation space and extending in a direction in which the first substrate and the second substrate are spaced from each other, the chip spacer including a first end portion connected to the at least one semiconductor chip, and a second end portion connected to one of the first and second substrates, and the chip spacer being configured to space the third substrate and any one of the first and second substrates.

For example, the third substrate may include: a film portion extending along the at least one conductive pattern and made of a flexible material to insulate the at least one conductive pattern; and a plurality of terminal portions formed at first and second opposite end portions of the conductive pattern and connected to the outside and the signal pad of the at least one semiconductor chip, and the power module may further include: a first lead including one end portion connected to the other end portion of the third substrate, and the other end portion connected to the outside and configured to electrically connect the semiconductor chip and the outside thereof; and a second lead connected to the first substrate and the second substrate and configured to electrically connect the first and second substrates and the outside thereof.

For example, the plurality of semiconductor chips may be joined to one surface of the first substrate directed toward the separation space, the first substrate may have a larger thickness than the second substrate, and the power module may further include a first cooling channel disposed in the other surface of the first substrate and configured so that a cooling fluid flows in the first cooling channel.

According to various embodiments of the present disclosure described above, the pattern on the substrate for the signal connection may be excluded so that the heat dissipation area of the semiconductor chip may be additionally ensured, and the substrate layout with various shapes may be applied.

Furthermore, the wire bonding for the signal connection may be excluded so that the height of the chip spacer may decrease, and the decrease in height of the spacer may improve heat dissipation performance and electric power performance.

Furthermore, the via spacer for forming the high-current path may be excluded, and the current path may be shortened so that the electric power performance may be improved, the internal space may be additionally ensured, and costs may be reduced.

The effects capable of being obtained by the present disclosure are not limited to the aforementioned effects, and other effects, which are not mentioned above, will be clearly understood by those skilled in the art from the following description.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a view exemplarily illustrating a cross-section of a power module according to an exemplary embodiment of the present disclosure.

FIG. 2 is a view exemplarily illustrating a portion of a plan view of the power module according to the exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION OF THE PRESENT DISCLOSURE

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Specific structural or functional descriptions of embodiments of the present disclosure disclosed in the present specification or application are exemplified only for explaining the exemplary embodiments according to an exemplary embodiment of the present disclosure, the exemplary embodiments of the present disclosure may be carried out in various forms, and it should not be interpreted that the present disclosure is limited to the exemplary embodiments described in the present specification or application.

Because the exemplary embodiments of the present disclosure may be variously changed and may have various forms, specific embodiments will be illustrated in the drawings and described in detail in the present specification or application. However, the descriptions of the specific embodiments are not intended to limit embodiments according to the concept of the present disclosure to the specific embodiments, but it should be understood that the present disclosure covers all modifications, equivalents and alternatives falling within the spirit and technical scope of the present disclosure.

Unless otherwise defined, all terms used herein, including technical or scientific terms, include the same meaning as commonly understood by those skilled in the art to which the present disclosure pertains. The terms such as those defined in commonly used dictionaries should be interpreted as having meanings consistent with meanings in the context of related technologies and should not be interpreted as ideal or excessively formal meanings unless explicitly defined in the present specification.

Hereinafter, various exemplary embodiments included in the present specification will be described in detail with reference to the accompanying drawings. The same or similar constituent elements are assigned with the same reference numerals regardless of reference numerals, and the repetitive description thereof will be omitted.

The suffixes “module”, “unit”, “part”, and “portion” used to describe constituent elements in the following description are used together or interchangeably to facilitate the description, but the suffixes themselves do not have distinguishable meanings or functions.

In the description of the exemplary embodiments disclosed in the present specification, the specific descriptions of publicly known related technologies will be omitted when it is determined that the specific descriptions may obscure the subject matter of the exemplary embodiments disclosed in the present specification. Furthermore, it should be interpreted that the accompanying drawings are provided only to allow those skilled in the art to easily understand the exemplary embodiments disclosed in the present specification, and the technical spirit disclosed in the present specification is not limited by the accompanying drawings, and includes all alterations, equivalents, and alternatives that are included in the spirit and the technical scope of the present disclosure.

The terms including ordinal numbers such as “first,” “second,” and the like may be used to describe various constituent elements, but the constituent elements are not limited by the terms. These terms are used only to distinguish one constituent element from another constituent element.

When one constituent element is described as being “coupled” or “connected” to another constituent element, it should be understood that one constituent element can be coupled or directly connected to another constituent element, and an intervening constituent element can also be present between the constituent elements. When one constituent element is described as being “directly coupled to” or “directly connected to” another constituent element, it should be understood that no intervening constituent element is present between the constituent elements.

Singular expressions include plural expressions unless clearly described as different meanings in the context.

In the present specification, it should be understood the terms “comprises,” “comprising,” “includes,” “including,” “containing,” “has,” “having” or other variations thereof are inclusive and therefore specify the presence of stated features, integers, steps, operations, elements, components, or combinations thereof, but do not preclude the presence or addition of one or more other features, integers, steps, operations, elements, components, or combinations thereof.

A power module according to an exemplary embodiment of the present disclosure may provide an internal structure which may use a third substrate, which includes a conductive pattern, to define a signal connection route and use first and second leads, which are joined to first and second substrates, to exclude a pattern of a substrate for signal connection, wire bonding, and a via spacer for forming a high-current path, improving heat dissipation performance and electric power performance of the power module.

Hereinafter, the power module according to the exemplary embodiment of the present disclosure will be described in detail with reference to the drawings.

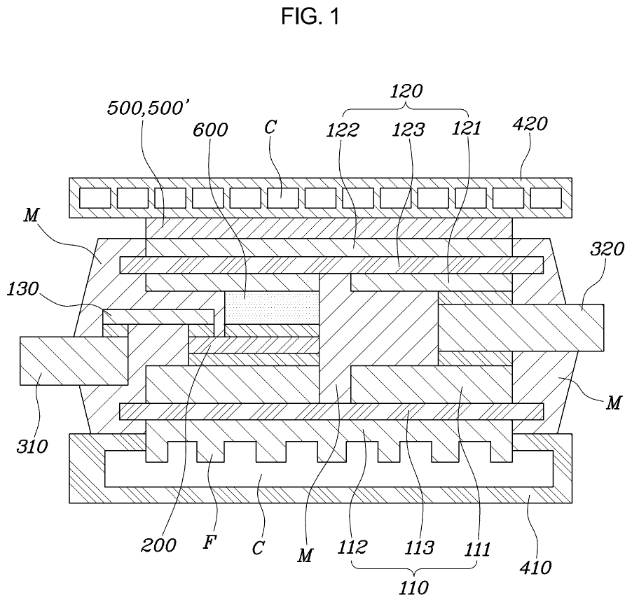

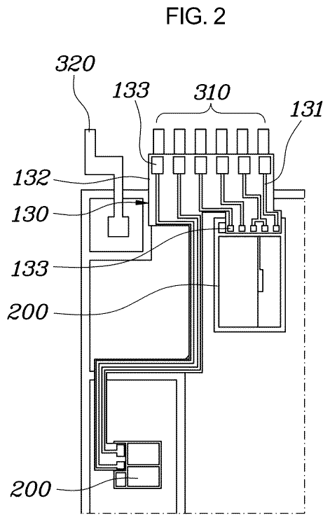

FIG. 1 is a view exemplarily illustrating a cross-section of a power module according to an exemplary embodiment of the present disclosure, and FIG. 2 is a view exemplarily illustrating a portion of a plan view of the power module according to the exemplary embodiment of the present disclosure.

With reference to FIG. 1 and FIG. 2 together, the power module according to the exemplary embodiment of the present disclosure may include a first substrate 110, a second substrate 120, a semiconductor chip 200, a third substrate 130, a first lead 310, a second lead 320, a first cooling channel 410, a second cooling channel 420, a chip spacer 600, and the like. However, FIG. 1 and FIG. 2 mainly illustrate constituent elements related to the description of the exemplary embodiment of the present disclosure. However, an actual power module may, of course, be implemented by including more or fewer constituent elements. Hereinafter, the components will be described.

The first substrate 110 and the second substrate 120 are spaced from each other. One surface and the other surface of each of the first and second substrates 110 and 120 may have metal layers 111, 112, 121, and 122, and insulation layers 113 and 123 may be provided between the metal layers 111, 112, 121, and 122.

At least one semiconductor chip 200 may be disposed in a separation space between the first substrate 110 and the second substrate 120, and the semiconductor chip 200 may include a signal pad to implement signal connection with the outside thereof.

Furthermore, at least one third substrate 130 may be disposed in the separation space between the first substrate 110 and the second substrate 120. The at least one third substrate 130 may include at least one conductive pattern 131 with one end portion electrically connected to the signal pad of at least one of the semiconductor chips 200, and the other end extended outwardly from the first substrate 110 and the second substrate 120 and have a smaller thickness than the first substrate 110 and the second substrate 120.

Because the third substrate 130 connects the semiconductor chip 200 to the outside of the power module, it is possible to exclude circuit patterns formed on the first and second substrates 110 and 120 to implement the signal connection. Therefore, it is possible to ensure a heat dissipation area of the first and second substrates 110 and 120 and apply various layouts to the first and second substrates 110 and 120. A structural constraint, which is caused when a layout having a complicated switching configuration is applied, may be eliminated, improving electric power performance.

Furthermore, because the third substrate 130 connects the semiconductor chip 200 and the outside of the power module, wire bonding for connecting the semiconductor chip 200 to the outside may be excluded so that the third substrate 130 has a small thickness, eliminating a minimum height constraint for wire bonding. Because the minimum height constraint is eliminated, a spacing distance between the first substrate 110 and the second substrate 120 may be shortened so that a current path may be shortened, which may mitigate deterioration in electric power performance caused by parasitic components and the like.

At least one third substrate 130 may include a film portion 132 extending along at least one of the conductive patterns 131 and made of a flexible material to insulate the conductive patterns 131, and a plurality of terminal portions 133 each provided at two opposite end portions of the conductive pattern 131 and configured to connect the signal pad of at least one of the semiconductor chips 200 to the outside thereof. The third substrate 130 may be implemented as a flexible printed circuit board (PFBC).

Meanwhile, the power module according to the exemplary embodiment of the present disclosure may further include the first lead 310 including one end portion connected to the other end portion of the third substrate 130, and the other end portion connected to the outside and configured to electrically connect the semiconductor chip 200 to the outside thereof. Because a signal connection route is defined between the inside and the outside of the power module by the first lead 310 and the third substrate 130, the first lead 310 may be expressed as a signal lead because the first lead 310 defines the signal connection route.

Furthermore, the power module according to the exemplary embodiment of the present disclosure may further include the second lead 320 connected to the first and second substrates 110 and 120 and configured to electrically connect the first and second substrates 110 and 120 to the outside thereof. The second lead 320 may define a signal connection route or a high-current path between the inside and outside the power module and be expressed as a signal or power lead depending on the defined route.

The second lead 320 may extend outwardly from the inside of the separation space between the first substrate 110 and the second substrate 120. In the separation space, one surface of the second lead 320 may be joined to the first substrate 110, and the other surface of the second lead 320 may be joined to the second substrate 120. In the instant case, the joining process may be performed by soldering, sintering, or the like, for example. Because the second lead 320 is connected to both the first substrate 110 and the second substrate 120, it is possible to eliminate a separate via spacer for connecting the first substrate 110 and the second substrate 120 spaced from each other.

Because the via spacer is excluded because of the second lead 320, a current path, through which high current flows, may be shortened, which may improve electric power performance of the power module and reduce material costs required to provide the via spacer.

The third substrate 130 may be used to exclude the wire bonding, and the second lead 320 may be used to exclude the via spacer so that a structural constraint on the height of the inside of the power module may be mitigated, and the spacing distance between the first substrate 110 and the second substrate 120 may be further shortened.

Meanwhile, the first substrate 110 and the second substrate 120 may have different thicknesses. In case that at least one semiconductor chip 200 is joined to one surface directed toward the separation space of the first substrate 110, the first substrate 110 may have a larger thickness than the second substrate 120. In the instant case, as the thickness of the first substrate 110 increases, the heat dissipation area may be ensured, which may be advantageous in implementing a heat sink-integrated structure on the first substrate on which the semiconductor chip 100 is disposed.

In the instant case, the first cooling channel 410, through which a cooling fluid C flows, may be disposed in the other surface of the first substrate 110, and the performance in cooling the first substrate 110 may be additionally improved by the first cooling channel 410.

A heat sink integrated with the first substrate 110 may be implemented by forming cooling fins F formed on the other surface of the first substrate 110 and configured to come into contact with the cooling fluid C. Therefore, the cooling efficiency may be improved by the first cooling channel 410.

Meanwhile, in addition to the first cooling channel in the first substrate 110, the second cooling channel 420, through which the cooling fluid C flows, may be disposed in one surface of the second substrate 120 directed toward the outside thereof. In the instant case, the second cooling channel 420 may be thermally connected to the second substrate through a heat transfer material 500 disposed between one surface of the second substrate 120 and the second cooling channel 420. Alternatively, the second cooling channel 420 may be thermally connected to one surface of the second substrate 120 by being joined to one surface of the second substrate 120 through a joining material 500′. Meanwhile, alternatively, the heat sink may also be integrated with the second substrate 120, and the second cooling channel 420 may be implemented in the same way as the first cooling channel 410.

In an exemplary embodiment of the present invention, the second cooling channel 420 is formed of a plurality of channels so as to increase contact surface of the second cooling channel 420 with the coolant.

Meanwhile, the power module according to the exemplary embodiment of the present disclosure may further include at least one chip spacer 600 disposed in the separation space between the first substrate 110 and the second substrate 120 and extending in the direction in which the first substrate 110 and the second substrate 120 are spaced from each other, the chip spacer 600 including one end portion connected to at least one semiconductor chip 200, and the other end portion connected to any one of the first substrate 110 and the second substrate 120, and the chip spacer 600 being configured to space the third substrate 130 and any one of the first substrate 110 and the second substrate 120.

In the instant case, because the wire bonding and the via spacer are excluded, the chip spacer 600 may have a comparatively small height. Therefore, the spacing distance between the first substrate 110 and the second substrate 120 may be shortened, and the electric power performance may be improved.

According to various embodiments of the present disclosure described above, the pattern on the substrate for the signal connection may be excluded so that the heat dissipation area of the semiconductor chip may be additionally ensured, and the substrate layout with various shapes may be applied.

Furthermore, the wire bonding for the signal connection may be excluded so that the height of the chip spacer may decrease, and the decrease in height of the spacer may improve heat dissipation performance and electric power performance.

Furthermore, the via spacer for forming the high-current path may be excluded, and the current path may be shortened so that the electric power performance may be improved, the internal space may be additionally ensured, and costs may be reduced.

Furthermore, the power module according to the exemplary embodiment of the present disclosure may further include a molding material M. The molding material M may encase the at least a portion of the first to third substrates 110, 120, 130, the first and second lead 310, 320 and the chip spacer 600. For example, the molding material M may be implemented with materials such as epoxy molding compound (EMC) to protect the components constituting the power module from moisture, heat, shock, etc.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
first and second substrates spaced from each other;
at least one semiconductor chip disposed in a separation space located between the first and second substrates; and
at least one third substrate disposed in the separation space located between the first and second substrates,
wherein the at least one third substrate includes at least one conductive pattern including a first end portion electrically connected to a signal pad of the at least one semiconductor chip, and a second end portion extended outwardly from the first and second substrates and connected to an outside of the power module, the at least one third substrate having a smaller thickness of each of the first and second substrates.

2. The power module of claim 1, wherein the at least one third substrate includes:
a film portion extending along the at least one conductive pattern and including a flexible material to insulate the at least one conductive pattern; and
a plurality of terminal portions formed at first and second opposite end portions of the at least one conductive pattern and connected to the outside and the signal pad of the at least one semiconductor chip.

3. The power module of claim 1, further including:
a first lead including a first end portion connected to the second end portion of the at least one third substrate, and a second end portion connected to the outside of the power module, the first lead being configured to electrically connect the second end portion of the at least one semiconductor chip and the outside.

4. The power module of claim 1, further including:
a second lead connected to the first and second substrates and electrically connecting the first and second substrates and the outside of the power module.

5. The power module of claim 4, wherein the second lead extends outwardly from an inside of the separation space formed between the first substrate and the second substrate, a first surface of the second lead is joined to the first substrate in the separation space, and a second surface of the second lead is joined to the second substrate.

6. The power module of claim 1, wherein the first substrate and the second substrate have different thicknesses.

7. The power module of claim 6, wherein the at least one semiconductor chip is joined to a first surface of the first substrate directed toward the separation space, and the first substrate has a larger thickness than the second substrate.

8. The power module of claim 7,
wherein the first substrate includes a first metal layer, a second metal layer and an insulation layer between the first metal layer and the second metal layer, and
wherein the at least one semiconductor chip is joined to the first metal layer of the first substrate, and
wherein a first cooling channel is disposed on the second metal layer and a cooling fluid flows in the first cooling channel.

9. The power module of claim 8,
wherein the second metal layer includes at least a cooling fin disposed in the first cooling channel.

10. The power module of claim 7, further including:
a first cooling channel disposed on a second surface of the first substrate, and a cooling fluid flows in the first cooling channel.

11. The power module of claim 10, wherein a cooling fin is formed on the second surface of the first substrate and provided to be in contact with the cooling fluid.

12. The power module of claim 7, further including:
a second cooling channel disposed on one surface of the second substrate directed toward the outside, and a cooling fluid flows in the second cooling channel.

13. The power module of claim 12, wherein the second cooling channel is thermally connected to the second substrate through a heat transfer material disposed between the one surface of the second substrate and the second cooling channel.

14. The power module of claim 12, wherein the second cooling channel is joined to the one surface of the second substrate.

15. The power module of claim 1, further including:
at least one chip spacer disposed in the separation space and extending in a direction in which the first substrate and the second substrate are spaced from each other, the chip spacer including a first end portion connected to the at least one semiconductor chip, and a second end portion connected to one of the first and second substrates, and the at least one chip spacer being configured to space the at least one third substrate and the one of the first and second substrates.

16. The power module of claim 1, wherein the at least one third substrate includes:
a film portion extending along the at least one conductive pattern and including a flexible material to insulate the at least one conductive pattern; and
a plurality of terminal portions formed at first and second opposite end portions of the at least one conductive pattern and connected to the outside and the signal pad of the at least one semiconductor chip, and
wherein the power module further includes:
a first lead including a first end portion connected to the second end portion of the at least one third substrate, and a second end portion connected to the outside and configured to electrically connect the at least one semiconductor chip and the outside; and
a second lead connected to the first substrate and the second substrate and configured to electrically connect the first and second substrates and the outside.

17. The power module of claim 16,
wherein a plurality of semiconductor chips is joined to a first surface of the first substrate directed toward the separation space,
wherein the first substrate has a larger thickness than the second substrate, and
wherein the power module further includes a first cooling channel disposed in a second surface of the first substrate and configured so that a cooling fluid flows in the first cooling channel.
